(19) United States
(12) Patent Application Publication
(10) Pub. No.: US 2026/0035781 A1
(43) Pub. Date: Feb. 5, 2026

(54) DEPOSITION APPARATUS

(71) Applicant: SAMSUNG ELECTRONICS CO., LTD., Suwon-si (KR)

(72) Inventors: June Hyun HAN, Suwon-si (KR); Sunghyup KIM, Suwon-si (KR); Jeongdu KIM, Suwon-si (KR); Seung-Yul PARK, Suwon-si (KR); Seung-Yong HAN, Suwon-si (KR)

(21) Appl. No.: 19/090,060

(22) Filed: Mar. 25, 2025

(30) Foreign Application Priority Data
Aug. 1, 2024 (KR) 10-2024-0102429

(51) Int. Cl. C23C 14/54; C23C 14/34

(52) U.S. Cl. CPC C23C 14/541; C23C 14/34; C23C 14/545

(57) ABSTRACT

A deposition apparatus includes a chamber configured to accommodate a target substrate that is configured to discharge a target material, a deposition substrate on which a deposition layer including the target material is formed, and an electrode substrate in contact with the deposition substrate, a voltage applying device configured to apply a voltage to the target substrate and the electrode substrate, a temperature measurement part configured to measure a temperature of the deposition substrate, a controller configured to calculate at least one of a temperature change rate and an absolute value of the temperature change rate based on a process time through the temperature of the deposition substrate measured in the temperature measurement part, compare the absolute value of the calculated temperature change rate and a preset threshold temperature change rate, control operation of the voltage applying device, and perform a deposition process for forming the deposition layer.

### CROSS-REFERENCE TO RELATED APPLICATION(S)

This application claims the benefit of Korean Patent Application No. 10-2024-0102429, filed on Aug. 1, 2024, in the Korean Intellectual Property Office, the disclosure of which is incorporated herein by reference in its entirety.

### BACKGROUND

### 1. Field of the Invention

Example embodiments relate to a deposition apparatus.

### 2. Description of the Related Art

A semiconductor process includes the process of manufacturing various thin films. Generally, the process of manufacturing thin films may be performed through deposition. Chemical vapor deposition (CVD), physics vapor deposition (PVD), atomic layer deposition (ALD), and the like are known as deposition manners.

PVD is known as a manner of depositing a target material for deposition on a substrate and forming a deposition layer. For example, PVD may be classified into thermal evaporation, electron-beam (E-beam) evaporation, and sputtering.

It is advantageous to perform deposition by heating a substrate to high temperatures rather than depositing at room temperature for uniformity in the deposition layer. However, when performing deposition while heating a substrate to high temperatures, the formed deposition layer has higher thermal stress as being closer to the substrate. This is because, as being closer to the substrate, the deposition layer is formed at relatively lower temperatures and then a sharp temperature change occurs due to the heating of the substrate.

Consequently, the deposition layer has a greater difference between the thermal stresses of regions close to the substrate and far from the substrate, which may lead to the growth of whiskers and negatively impact yield.

### SUMMARY OF THE INVENTION

An aspect provides a deposition apparatus that may minimize the generation and growth of whiskers and improve yield reduction.

Example embodiments are not limited to the technical features described above, and other unstated technical features may be made apparent to those skilled in the art from the following description.

According to an aspect, there is provided a deposition apparatus including a chamber configured to accommodate a target substrate that is configured to discharge a target material, a deposition substrate on which a deposition layer including the target material is formed, and an electrode substrate in contact with the deposition substrate, a voltage applying device configured to apply a voltage to the target substrate and the electrode substrate, a temperature measurement part configured to measure a temperature of the deposition substrate, a controller configured to calculate at least one of a temperature change rate and an absolute value of the temperature change rate based on a process time through the temperature of the deposition substrate measured in the temperature measurement part, compare the absolute value of the calculated temperature change rate and a preset threshold temperature change rate, control operation of the voltage applying device, and perform a deposition process for forming the deposition layer.

According to another aspect, there is also provided a deposition apparatus including a chamber configured to accommodate a target substrate that is configured to discharge a target material, a deposition substrate on which a deposition layer including the target material is formed, and an electrode substrate in contact with the deposition substrate, a voltage applying device configured to apply a voltage between the target substrate and the electrode substrate, a temperature measurement part configured to measure a temperature of the deposition substrate, and a controller configured to calculate thermal stress of a first surface of the deposition layer in contact with the deposition substrate and thermal stress of a second surface opposite to the first surface by the temperature of the deposition substrate measured in the temperature measurement part, calculate a thermal stress difference that is a difference between the thermal stress of the first surface and the thermal stress of the second surface, compare an absolute value of the thermal stress difference and a preset threshold thermal stress difference, control operation of the voltage applying device, and perform a deposition process for forming the deposition layer.

According to another aspect, there is also provided a deposition apparatus including a chamber configured to accommodate a target substrate that is configured to discharge a target material, a deposition substrate on which a deposition layer including the target material is formed, and an electrode substrate in contact with the deposition substrate, a voltage applying device configured to apply a negative DC voltage to the target substrate and a positive DC voltage to the electrode substrate, a temperature measurement part configured to measure a temperature of the deposition substrate, and a controller configured to calculate thermal stress of a first surface of the deposition layer in contact with the deposition substrate and thermal stress of a second surface opposite to the first surface by the temperature of the deposition substrate measured in the temperature measurement part, calculate a thermal stress difference that is a difference between the thermal stress of the first surface and the thermal stress of the second surface, compare an absolute value of the calculated thermal stress difference and a preset threshold thermal stress difference, control operation of the voltage applying device, and perform a deposition process for forming the deposition layer. The controller may be configured to, when the absolute value of the calculated thermal stress difference is greater than the preset threshold thermal stress difference, control that the voltage applying device in an operating state changes to a stop state, or control that the voltage applying device in the stop state maintains the stop state, when the absolute value of the calculated thermal stress difference is equal to or less than the preset threshold thermal stress difference, control that the voltage applying device in the stop state changes to the operating state, or control that the voltage applying device in the operating state maintains the operating state, and perform a plurality of deposition processes and form the deposition layer that has a final target thickness. At a start time point when the absolute value of the calculated thermal stress is equal to the preset threshold thermal stress difference, the voltage applying device may be in the stop state, and the controller may be configured to control that the voltage applying device in the stop state changes to the operating state, or control that the voltage applying device in the stop state maintains the stop state and then changes to the operating state and control that the voltage applying device maintains the operating state until an s-th deposition layer having an s-th thickness is formed while the absolute value of the calculated thermal stress difference is equal to or less than the preset threshold thermal stress difference. After the start time point, at a finish time point when the calculated thermal stress difference is a negative number and the absolute value of the calculated thermal stress difference is equal to the preset threshold thermal stress difference, the voltage applying device may be in the stop state, and the controller may be configured to control that the voltage applying device in the stop state maintains the stop state and then changes to the operating state and control that the voltage applying device maintains the operating state until an f-th deposition layer having an f-th thickness is formed and the deposition layer having the final target thickness is formed while the absolute value of the calculated thermal stress difference is equal to or less than the preset threshold thermal stress difference. The s-th deposition layer and the f-th deposition layer may be a portion of the deposition layer, the f-th thickness may be greater than the s-th thickness, and the s-th thickness and the f-th thickness may be less than the final target thickness.

Additional aspects of example embodiments will be set forth in part in the description which follows and, in part, will be apparent from the description, or may be learned by practice of the disclosure.

According to example embodiments, it is possible to provide a deposition apparatus that may minimize the generation and growth of whiskers and improve yield reduction.

Effects of example embodiments are not limited to those described above, and other unstated effects may be clearly understood by those skilled in the art from the following description.

### BRIEF DESCRIPTION OF THE DRAWINGS

The drawings of the present disclosure are shown according to example embodiments, and a ratio of width, length, or height (or thickness) of each element is to describe the present disclosure in detail and the ratio may be different from the actual ratio. Further, in a coordinate system shown in the drawings, each axis may be perpendicular to one another, and a direction pointed by an arrow may be +direction and a directly opposite direction (a direction turned by 180 degrees) to the direction pointed by the arrow may be —direction.

These and/or other aspects, features, and advantages of the invention will become apparent and more readily appreciated from the following description of example embodiments, taken in conjunction with the accompanying drawings of which:

FIG. 1 is a cross-sectional view schematically showing a deposition apparatus according to an example embodiment of the present disclosure;

FIGS. 2 to 5 are flowcharts for illustrating a manner of performing a deposition process by a deposition apparatus according to a first example embodiment of the present disclosure;

FIGS. 6 and 7 are flowcharts for illustrating a manner of performing a deposition process by a deposition apparatus according to a second example embodiment of the present disclosure;

FIGS. 8 to 11 are flowcharts for illustrating a manner of performing a deposition process by a deposition apparatus according to a third example embodiment of the present disclosure; and

FIGS. 12 and 13 are flowcharts for illustrating a manner of performing a deposition process by a deposition apparatus according to a fourth example embodiment of the present disclosure.

### DETAILED DESCRIPTION

Before describing the present disclosure in detail, the words and terminologies used in the specification and claims may not be construed as limited to common or dictionary meanings. In addition, the words and terminologies may be construed as meanings and conceptions coinciding with the technical spirit of the present disclosure under a principle that the inventor(s) may appropriately define the conception of the terminologies to explain the invention in the optimum manner. The example embodiments described in the specification and the configurations illustrated in the drawings are no more than the most preferred example embodiments of the present disclosure and do not fully cover the spirit of the present disclosure. Therefore, there may be various equivalents and modifications that may replace those when this application is filed.

Like reference numerals or letters in each drawing attached to the specification may refer to components or elements performing substantially like functions. For convenience of description and understanding, the same reference numeral or letter may be used for description in different example embodiments. In other words, even though elements with the same reference numeral are illustrated in a plurality of drawings, all of the plurality of drawings may not represent a single example embodiment.

When an element is referred to as being “directly on,” “contacting,” or “in contact with” another element herein, it may be understood that the element may be in direct contact with or directly connected to another element and there are no intervening elements present in between.

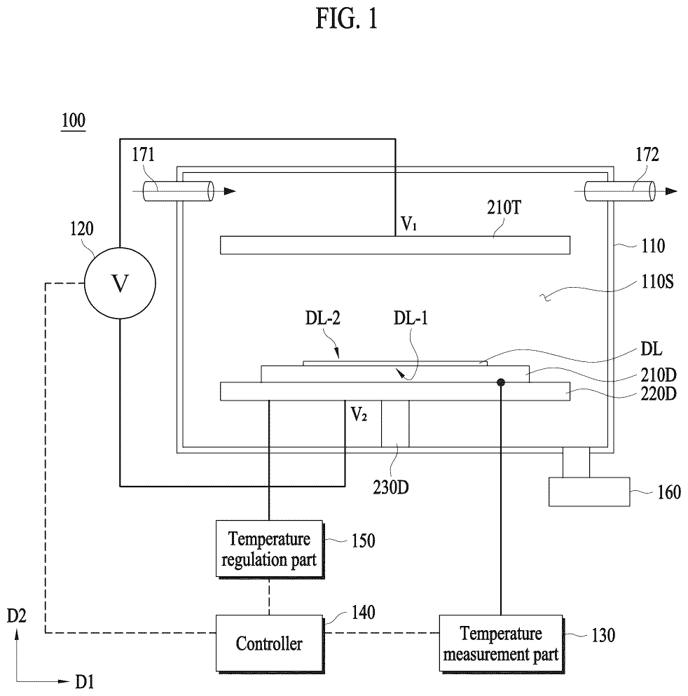

Further, when an element is referred to as being “above” or “on an upper surface of” another element herein, it may be understood that the element is present above based on a vertical direction or, for example, above based on direction +D2 in a drawing (FIG. 1), and it may be understood that the element may be in direct contact with or directly connected to another element or an intervening element may be present in between. When an element is referred to as being “on” another element herein may also be similarly understood.

Further, when an element is referred to as being “below” or “on a lower surface of” another element herein, it may be understood that the element is present below based on a vertical direction or, for example, below based on direction −D2 in a drawing (FIG. 1), and it may be understood that the element may be in direct contact with or directly connected to another element or an intervening element may be present in between. When an element is referred to as being “under” another element herein may also be similarly understood.

Other similar expressions describing position relationships between elements may also be similarly construed as above.

In the descriptions below, a singular expression includes a plural expression unless apparently otherwise defined by context. In the present disclosure, it may be understood that terms such as “comprise or include” and “consist of” are intended to indicate the presence of a feature, a number, a step, an operation, an element, a component, or a combination thereof which are described in the specification and not intended to previously exclude the possibility of the presence or addition of one or more other features, numbers, steps, operations, elements, components, or combinations thereof.

In addition, expressions such as upper side, upper surface, lower side, lower surface, side surface, front surface, and rear surface hereinafter are represented based on a direction illustrated in a drawing and may be represented otherwise when the direction of a corresponding object changes.

Further, terms including ordinal numbers such as “first” and “second” may be used to differentiate between elements in the specification and claims. These ordinal numbers may be used to differentiate identical or similar elements from each other, and the use of the ordinal numbers may not limit the meanings of terms. As an example, an element combined with an ordinal number is not to be construed as the using order or arrangement order thereof is limited by the ordinal number. In some cases, each ordinal number may also be used by replacing each other.

FIG. 1 is a cross-sectional view schematically showing a deposition apparatus 100 according to an example embodiment of the present disclosure. The deposition apparatus 100 according to an example embodiment of the present disclosure may be described based on a physics vapor deposition (PVD) apparatus for convenience of description. In an example, the deposition apparatus 100 may be the PVD apparatus and specifically may be a sputtering apparatus. In an example, the deposition apparatus 100 may be described based on the sputtering apparatus. However, in an example, the deposition apparatus 100 is not limited to the PVD apparatus and may also be used for deposition apparatuses using other manners.

In the present disclosure, one of the directions parallel to a surface of a deposition substrate 210D may be referred to as a first direction D1. In addition, a direction perpendicular to the surface of the deposition substrate 210D may be referred to as a second direction D2, and the second direction D2 may be perpendicular to the first direction D1.

In an example, the deposition apparatus 100 may include a chamber 110 that accommodates a target substrate 210T discharging a target material, a deposition substrate 210D on which a deposition layer DL including the target material is formed, and an electrode substrate 220D in contact with the deposition substrate 210D. In an example, the deposition apparatus 100 may include a voltage applying device 120 that applies a voltage to the target substrate 210T and the electrode substrate 220D.

In an example, the chamber 110 may provide a deposition process space 110S that is a physical space where a deposition process is performed. In addition, the chamber 110 may seal the deposition process space 110S. In an example, the chamber 110 may be electrically grounded.

In an example, the chamber 110 may be a vacuum chamber that may create a vacuum environment in the deposition process space 110S. The deposition apparatus 100 may include a vacuum pump 160 so that the deposition process space 110S may become the vacuum environment. Here, vacuum may refer to about 10⁻¹ Torr to 10⁻⁴ Torr or about 10⁻² Torr to 10⁻³ Torr pressure. Though not illustrated in the drawings, the vacuum described above may be implemented through a pressure gage that measures the pressure within the deposition process space 110S and an output of the vacuum pump 160 and may also be controlled through electrical signals by a controller 140 to be described below but is not limited thereto.

In an example, the chamber 110 may have enough strength and stiffness to bear the vacuum described above. In an example, the chamber 110 may have a protective film (not shown) disposed on an inner wall, and the protective film may minimize the contamination of the inner wall of the chamber 110 while the deposition process is performed.

In an example, the target substrate 210T may include various materials depending on the types of the deposition layer DL to be formed. The target material that is a material included in the target substrate 210T may be, for example, a metal material. For example, the metal material may be, but is not limited to, aluminum (Al), titanium (Ti), indium (In), cadmium (Cd), copper (Cu), zinc (Zn), tantalum (Ta), or tungsten (W). The target material included in the target substrate 210T may be deposited on the deposition substrate 210D through the deposition process to form the deposition layer DL.

In an example, the target substrate 210T may be an electrode per se, to which a voltage may be directly applied from the voltage applying device 120. In an example, a first voltage V₁ may be applied to the target substrate 210T from the voltage applying device 120, and the first voltage V₁ may be, for example, a negative voltage. In this case, the target substrate 210T may be referred to as a cathode substrate.

In an example, the deposition apparatus 100 may include a target holder that fixes a position of the target substrate 210T, though not separately illustrated. In an example, the target holder may fix the position of the target substrate 210T within the deposition process space 110S so that one surface of the target substrate 210T faces toward the electrode substrate 220D from a ceiling portion of the chamber 110.

In an example, the target holder may include a target plate (not shown) combined with the ceiling portion of the chamber 110, and the target substrate 210T may be combined with the target plate. In this case, a voltage may be applied to the target plate from the voltage applying device 120, and the voltage applied to the target plate may be transmitted to the target substrate 210T.

In an example, the target holder may include a cooling part (not shown) that may cool the target substrate 210T. In an example, the cooling part may be combined with the target substrate 210T and may dissipate heat so that the target substrate 210T may not be overheated by heat generated in the target substrate 210T.

In an example, the deposition layer DL may be formed mainly on one surface of the deposition substrate 210D facing the target substrate 210T through the deposition process. However, the deposition layer DL is not formed at this position alone and may also be formed at other regions of the deposition substrate 210D.

In an example, another surface opposite to the one surface mainly on which the deposition layer DL is formed on the deposition substrate 210D may be in contact with the electrode substrate 220D. In an example, a voltage may be applied directly to the electrode substrate 220D from the voltage applying device 120. In an example, a second voltage V₂ having a polarity opposite to the first voltage V₁ may be applied to the electrode substrate 220D from the voltage applying device 120, and the second voltage V₂ may be, for example, a positive voltage. In this case, the electrode substrate 220D may be referred to as an anode substrate.

In an example, the deposition substrate 210D may be, but is not limited to, a silicon semiconductor substrate, a plastic substrate, a glass substrate, a compound semiconductor substrate, or a ceramic substrate.

In an example, the deposition apparatus 100 may include a support 230D that supports the electrode substrate 220D and the deposition substrate 210D. The support 230D may fix the electrode substrate 220D and may lift in the second direction D2 and may also rotate the electrode substrate 220D about a rotational axis of the second direction D2.

In an example, the voltage applying device 120 may apply a direct current (DC) voltage to the target substrate 210T and the electrode substrate 220D. In an example, the voltage applying device 120 may include a DC coil that supplies DC voltage or a radio frequency (RF) coil that provides RF power. Further, in an example, the voltage applying device 120 may apply a negative voltage to the target substrate 210T and a positive voltage to the electrode substrate 220D as described above. In an example, the voltage applying device 120 applying DC voltage may help secure uniformity in the deposition layer DL.

In an example, the deposition apparatus 100 may include an inflow part 171 so that an operation gas may be introduced into the deposition process space 110S. In addition, the deposition apparatus 100 may include an outflow part 172 that releases outwards an impurity gas generated in the deposition process in addition to the operation gas. In an example, the inflow part 171 and the outflow part 172 may include a valve (not shown) each independently, and the valve may operate through electrical signals from the controller 140 to be described below.

In an example, each valve of the inflow part 171 and the outflow part 172 may be closed while the deposition apparatus 100 performs the deposition process. In an example, when the deposition apparatus 100 is in a preparation process for performing the deposition process, the valve of the inflow part 171 may be open and the valve of the outflow part 172 may be closed. In an example, when the deposition apparatus 100 ends the deposition process, the valve of the inflow part 171 may be closed and the valve of the outflow part 172 may be open. Both an opening process (including opening degrees) and a closing process of the valve may be operated through electrical signals from the controller 140.

In an example, each of the inflow part 171 and the outflow part 172 may include a pump (not shown) so that a fluid (for example, gas) may move easily. The inflow part 171 may operate the pump and introduce the operation gas into the deposition process space 110S more easily. In addition, the outflow part 172 may operate the pump and release the impurity gas generated in the deposition process in addition to the operation gas outwards from the deposition process space 110S more easily. Each pump may be connected to the controller 140 and may be operated through electrical signals from the controller 140.

In an example, the operation gas may include an inert gas. The inert gas may refer to, for example, a gas that is an element in group 18 of the periodic table and, specifically, may be argon (Ar). The operation gas may be turned into a plasma within the chamber 110 of the vacuum environment by the voltage applying device 120, and the plasma operation gas may collide with the target substrate 210T and lead the target material to be discharged into the deposition process space 110S. The target material discharged into the deposition process space 110S may be deposited on the deposition substrate 210D to form the deposition layer DL.

In an example, the inflow part 171 may introduce a reaction gas into the deposition process space 110S. The reaction gas may react with the target material discharged into the deposition process space 110S by the plasma operation gas, and a reactant may be deposited on the deposition substrate 210D to form the deposition layer DL. Here, the reaction gas may be, for example, an oxygen gas (O₂), a nitrogen gas (N₂), an ammonia gas (NH₃), a methane gas (CH₄), an acetylene gas (C₂H₂), an ethane gas (C₂H₆), a propane gas (C₃H₈), or hydrogen sulfide (H₂S), and various substances may be used based on the types of the deposition layer DL in addition thereto. The deposition layer DL may include the target material per se and may include the target material that includes a reactant formed of a reaction with the reaction gas and is composed through a chemical combination within the reactant.

In an example, the deposition apparatus 100 may include a temperature measurement part 130 that measures a temperature of the deposition substrate 210D. The temperature measurement part 130 may be disposed outside the chamber 110 and may be a thermocouple extending to the deposition substrate 210D through a through hole (not shown) formed in the chamber 110. In an example, though not illustrated, the temperature measurement part 130 may be a pyrometer that measures a temperature with light through the through hole formed in the chamber 110. However, the type of the temperature measurement part 130 is not particularly limited as long as a device may measure a temperature of a portion of the deposition substrate 210D.

In an example, the deposition apparatus 100 may include a temperature regulation part 150 that exchanges heat energy so that the temperature of the deposition substrate 210D becomes a set temperature. The temperature regulation part 150 may include a heat exchange line and may be disposed outside the chamber 110. The heat exchange line may extend to the electrode substrate 220D or the deposition substrate 210D through the through hole (not shown) formed in the chamber 110.

In an example, when the temperature of the deposition substrate 210D is lower than the set temperature, the temperature regulation part 150 may transfer heat energy to the deposition substrate 210D. In an example, when the temperature of the deposition substrate 210D is higher than the set temperature, the temperature regulation part 150 may recover heat energy from the deposition substrate 210D. The temperature regulation part 150 may be connected to the controller 140 and operated through electrical signals from the controller 140. In an example, the temperature regulation part 150 may be a device that makes the temperature of the deposition substrate 210D become the set temperature or be maintained at the set temperature. In addition, the temperature of the deposition substrate 210D here may be measured through the temperature measurement part 130 described above.

In an example, the deposition apparatus 100 may include the controller 140 that is directly and indirectly connected to the elements included therein and controls operation of the elements to perform the deposition process for forming the deposition layer DL. Here, the direct connection may refer to a connection with contact through a wire or the like, and the indirect connection may refer to a connection without contact through a wireless communication or the like. In some cases, the element connected to the controller 140 may include a transmitting and receiving apparatus to transmit and receive data of an electronic signal form. The controller 140 may also include a transmitting and receiving apparatus to transmit and receive data of an electronic signal form to and from other elements. If necessary, the controller 140 may include a processor or processors configured to process an electronic signal.

In an example, the controller 140 may calculate a temperature change rate (ΔT_{S}) based on a process time through the temperature of the deposition substrate 210D measured in the temperature measurement part 130. In addition, the controller 140 may calculate an absolute value of the temperature change rate (ΔT_{S}) based on the process time. In an example, the temperature change rate (ΔT_{S}) based on the process time may be a temperature change between a short time interval, and the short time interval may be, but is not limited to, about 1 millisecond (ms), for example.

In the present disclosure, the process time may refer to the time to perform the deposition process and may be a term that encompasses an entire time related to the deposition process from the time for preparing the deposition process to the finish time. Further, a deposition time herein may refer to a time in which the voltage applying device 120 operates and deposition is performed in order that at least a portion of the deposition layer DL is formed on the deposition substrate 210D, and specifically, may refer to a time after finishing a preparation for the deposition process (in other words, in a state the deposition layer DL may be formed when the voltage applying device 120 operates) until the voltage applying device 120 in a stop state changes to an operating state and the voltage applying device 120 in an operating state changes to a stop state. In an example, multiple deposition times may be present within one process time, and a total sum of deposition times performed so that the deposition layer DL has a final target thickness may be referred to as a final deposition time. In an example, the final deposition time may be set based on deposition speed and the final target thickness of the deposition layer DL.

In an example, the controller 140 may compare the absolute value of the calculated temperature change rate (ΔT_{S}) and a preset threshold temperature change rate (ΔT_{C}) and control operation of the voltage applying device 120. The threshold temperature change rate (ΔT_{C}) may be set to any design value. Depending on the threshold temperature change rate (ΔT_{C}), a process speed or a quality of the deposition layer DL may vary. In an example, the threshold temperature change rate (ΔT_{C}) may be set to a suitable value obtained through a simulation program or the like based thereon. In an example, the threshold temperature change rate (ΔT_{C}) may be less than or equal to an arithmetic average of a highest temperature (T_{f}) of the deposition substrate 210D and a lowest temperature (Tᵢ) of the deposition substrate 210D which are measured in the temperature measurement part 130.

In an example, the threshold temperature change rate (ΔT_{C}) may consequently be less than or equal to an arithmetic average of the highest temperature (T_{f}) of the deposition substrate 210D and the lowest temperature (Tᵢ) of the deposition substrate 210D which are measured in the temperature measurement part 130. Accordingly, before performing the deposition process, the highest temperature (T_{f}) of the deposition substrate 210D and the lowest temperature (Tᵢ) of the deposition substrate 210D may be obtained through the simulation program described above or the like, and a suitable value less than or equal to the arithmetic average thereof may be set as the threshold temperature change rate (ΔT_{C}).

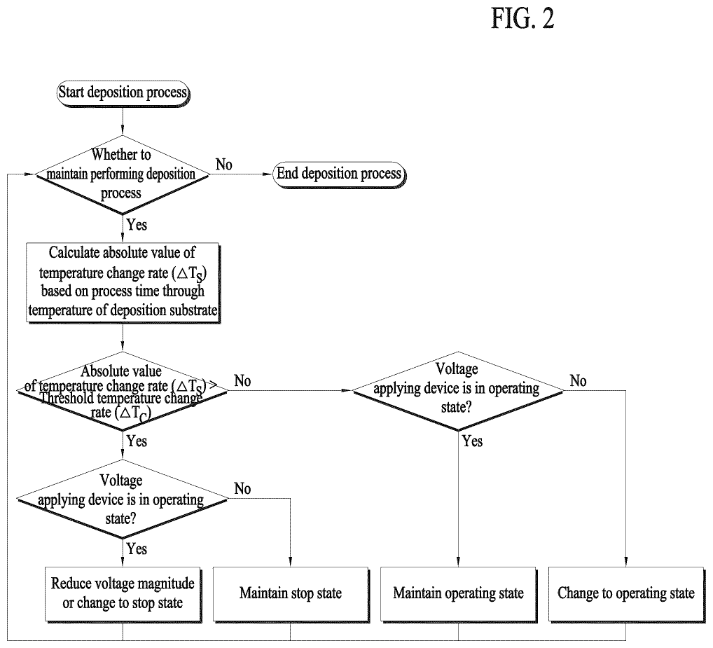

FIGS. 2 to 5 are flowcharts for illustrating a manner of performing a deposition process by the deposition apparatus 100 according to a first example embodiment of the present disclosure.

In an example, the controller 140 may determine whether to maintain performing the deposition process. Whether to maintain performing the deposition process may be determined depending on whether the thickness of the formed deposition layer DL is equal to the final target thickness, and when the thickness of the formed deposition layer DL is less than the final target thickness, performing the deposition process may be maintained, and when the thickness of the formed deposition layer DL is equal to the final target thickness, performing the deposition process may be stopped and the deposition process may finish. When the deposition process finishes, it may be controlled that the voltage applying device 120 directly changes to a stop state without identifying a relationship between the absolute value of the calculated temperature change rate (ΔT_{S}) and the threshold temperature change rate (ΔT_{C}). Further, in some cases, the controller 140 may open the valve of the outflow part 172 and operate the pump to control that the impurity gas generated during a deposition reaction is released outwards.

In an example, the controller 140 may start to perform the deposition process when the deposition layer DL is not formed, and in some cases, may open the valve of the inflow part 171 and operate the pump to introduce the operation gas into the deposition process space 110S. Then, the controller 140 may close the valve of the inflow part 171, stop the pump, and then operate the vacuum pump 160 to make the deposition process space 110S a vacuum environment so that the chamber 110 becomes a vacuum chamber. Then, the controller 140 may increase the temperature of the deposition substrate 210D with the temperature regulation part 150 and then control that the deposition layer DL is formed on the deposition substrate 210D in a control manner described above or to be described below.

Referring to FIG. 2, in an example, when the absolute value of the calculated temperature change rate (ΔT_{S}) is greater than the threshold temperature change rate (ΔT_{C}), the controller 140 may control that the voltage applying device 120 in an operating state applies a voltage with a magnitude reduced or changes to a stop state. When the magnitude of the voltage applied by the voltage applying device 120 is reduced, deposition speed may decrease. In an example, when the absolute value of the calculated temperature change rate (ΔT_{S}) is greater than the threshold temperature change rate (ΔT_{C}), the controller 140 may control that the voltage applying device 120 in a stop state maintains the stop state. In an example, when the absolute value of the calculated temperature change rate (ΔT_{S}) is equal to the threshold temperature change rate (ΔT_{C}) or less than the threshold temperature change rate (ΔT_{C}), the controller 140 may control that the voltage applying device 120 in a stop state changes to an operating state. In an example, when the absolute value of the calculated temperature change rate (ΔT_{S}) is equal to the threshold temperature change rate (ΔT_{C}) or less than the threshold temperature change rate (ΔT_{C}), the controller 140 may control that the voltage applying device 120 in an operating state maintains the operating state. Then, the controller 140 may re-determine whether to maintain performing the deposition process and control that the control manner described above is repeated or the deposition process is finished.

In an example, as the controller 140 controls the deposition process as described above, the generation and growth of whiskers may be minimized, which may improve yield reduction.

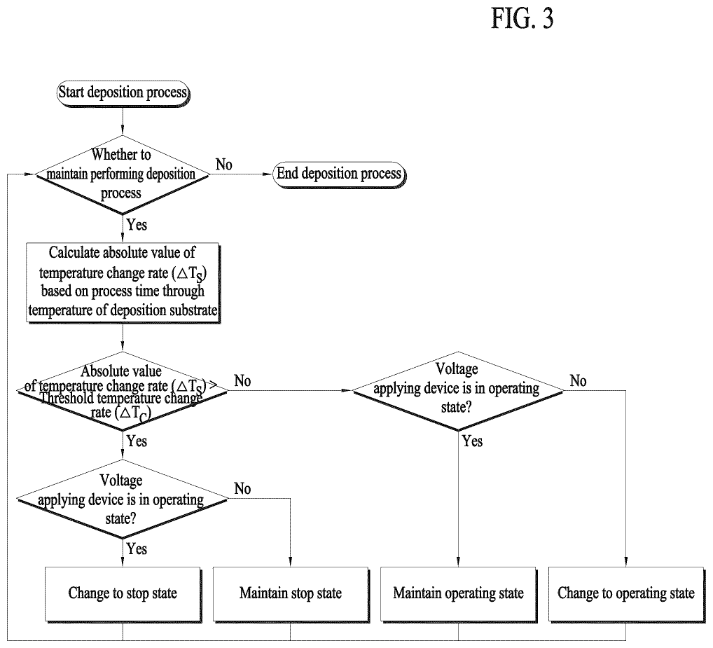

Referring to FIG. 3, in an example, when the absolute value of the calculated temperature change rate (ΔT_{S}) is greater than the threshold temperature change rate (ΔT_{C}), the controller 140 may control that the voltage applying device 120 in an operating state changes to a stop state. In other words, the controller 140 here may control that the voltage applying device 120 in the operating state directly changes to the stop state without reducing the magnitude of a voltage applied as in FIG. 2. The controller 140 controlling in this on-off manner may help secure uniformity in the deposition layer DL.

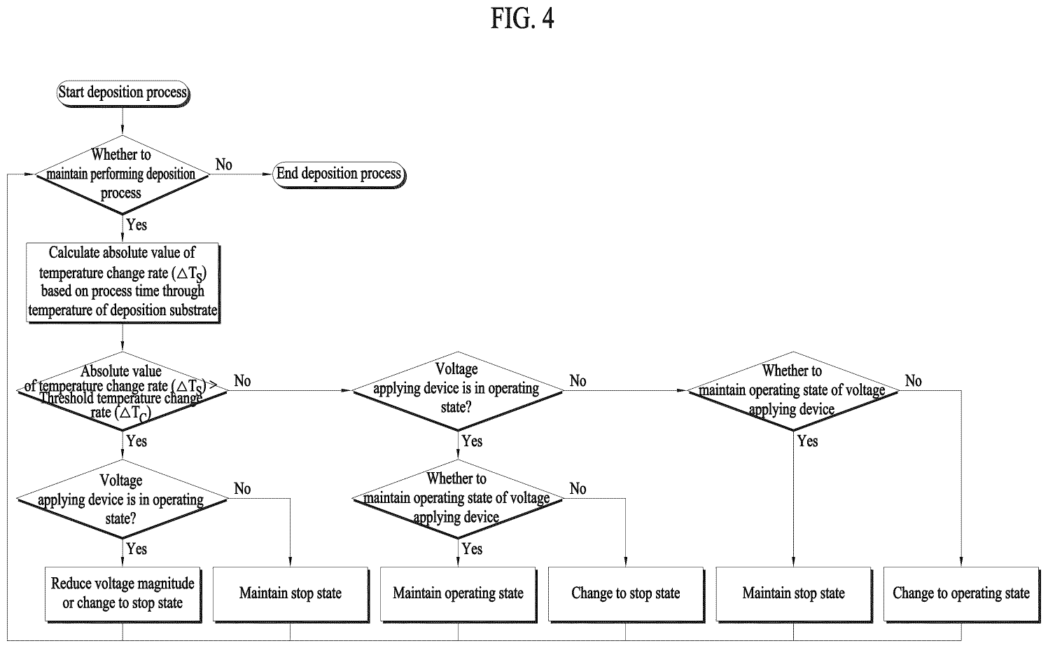

Referring to FIG. 4, in an example, when the absolute value of the calculated temperature change rate (ΔT_{S}) is greater than the threshold temperature change rate (ΔT_{C}), the controller 140 may control that the voltage applying device 120 in an operating state applies a voltage with a magnitude reduced or changes to a stop state. In an example, when the absolute value of the calculated temperature change rate (ΔT_{S}) is greater than the threshold temperature change rate (ΔT_{C}), the controller 140 may control that the voltage applying device 120 in a stop state maintains the stop state. In an example, when the absolute value of the calculated temperature change rate (ΔT_{S}) is equal to the threshold temperature change rate (ΔT_{C}) or less than the threshold temperature change rate (ΔT_{C}), the controller 140 may control that the voltage applying device 120 in a stop state maintains the stop state or changes to an operating state. Further, in an example, when the absolute value of the calculated temperature change rate (ΔT_{S}) is equal to the threshold temperature change rate (ΔT_{C}) or less than the threshold temperature change rate (ΔT_{C}), the controller 140 may control that the voltage applying device 120 in an operating state maintains the operating state or changes to a stop state. Then, the controller 140 may re-determine whether to maintain performing the deposition process and control that the control manner described above is repeated or the deposition process is finished.

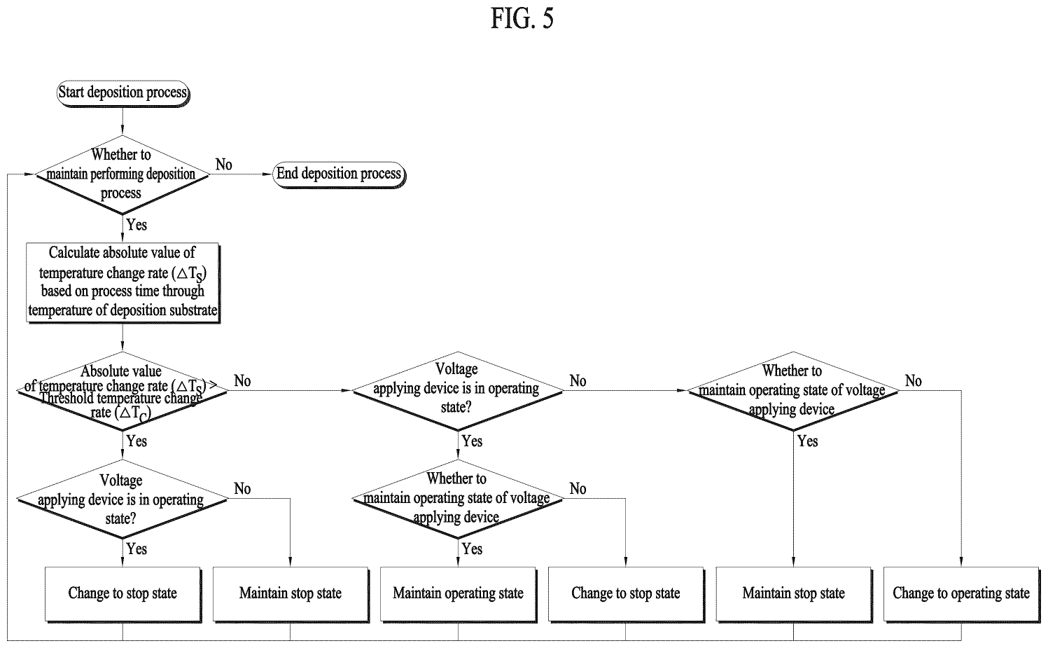

Referring to FIG. 5, in an example, when the absolute value of the calculated temperature change rate (ΔT_{S}) is greater than the threshold temperature change rate (ΔT_{C}), the controller 140 may control that the voltage applying device 120 in an operating state changes to a stop state. In other words, the controller 140 here may control that the voltage applying device 120 in the operating state directly changes to the stop state without reducing the magnitude of a voltage applied as in FIG. 4. The controller 140 controlling in this on-off manner may help secure uniformity in the deposition layer DL.

In an example, the controller 140 may perform a plurality of deposition processes and form the deposition layer DL that has the final target thickness. Performing the plurality of deposition processes may minimize shear stress excessively applied or unevenly applied to the formed deposition layer DL, enhance film quality, and help secure economic effectiveness in the processes.

In an example, as described above, the controller 140 may start performing the deposition process when the deposition layer DL is not formed. In this case, since a temperature rise rate of the deposition substrate 210D by the temperature regulation part 150 is high, the absolute value of the calculated temperature change rate (ΔT_{S}) may be greater than the preset threshold temperature change rate (ΔT_{C}). As the process time increases, the temperature of the deposition substrate 210D may be gradually stabilized and the temperature rise rate may be gradually decreased. In other words, the absolute value of the calculated temperature change rate (ΔT_{S}) may gradually decrease, and a start time point may be reached at which the calculated temperature change rate (ΔT_{S}) is a negative number and the absolute value of the calculated temperature change rate (ΔT_{S}) is first equal to the threshold temperature change rate (ΔT_{C}).

In an example, at the start time point when the absolute value of the calculated temperature change rate (ΔT_{S}) is equal to the threshold temperature change rate (ΔT_{C}), the voltage applying device 120 may be in a stop state. In addition, before the start time point, the voltage applying device 120 may be in the stop state. Specifically, in an example, the controller 140 may control that the voltage applying device 120 maintains the stop state before the start time point.

In an example, the controller 140 may control that the voltage applying device 120 in the stop state changes to an operating state. When the voltage applying device 120 operates, the deposition layer DL may be formed on the deposition substrate 210D.

In an example, the controller 140 may control that the voltage applying device 120 in the stop state maintains the stop state and then changes to the operating state. When the voltage applying device 120 operates, the deposition layer DL may be formed on the deposition substrate 210D.

In an example, the controller 140 may control that the voltage applying device 120 maintains the operating state until an s-th deposition layer having an s-th thickness is formed while the absolute value of the calculated temperature change rate (ΔT_{S}) is equal to or less than the threshold temperature change rate (ΔT_{C}). Here, the s-th deposition layer may be a portion of the deposition layer DL and the s-th thickness may be less than the final target thickness. In an example, when the controller 140 may control that the voltage applying device 120 changes to the operating state, the deposition layer DL may be formed and the temperature of the deposition substrate 210D may rise, which may lead to a gradual rise in the absolute value of the calculated temperature change rate (ΔT_{S}). Here, a maximum deposition time in which the voltage applying device 120 may be maintained in the operating state may be until the absolute value of the calculated temperature change rate (ΔT_{S}) becomes equal to the threshold temperature change rate (ΔT_{C}). In other words, a maximum value of the s-th thickness that is the thickness of the s-th deposition layer may be a thickness obtained when performing deposition until the absolute value of the calculated temperature change rate (ΔT_{S}) becomes equal to the threshold temperature change rate (ΔT_{C}).

In an example, the controller 140 may control that the voltage applying device 120 in a stop state changes to an operating state (in other words, directly changes to the operating state without maintaining the stop state), and in this case, the voltage applying device 120 may operate for time tₛ₁ during which an s-th first deposition layer having an s-th first thickness is formed while the absolute value of the calculated temperature change rate (ΔT_{S}) is less than or equal to the threshold temperature change rate (ΔT_{C}). Further, in an example, the controller 140 may control that the voltage applying device 120 in a stop state maintains the stop state and then changes to an operating state, and in this case, the voltage applying device 120 may operate for time tₛ₂ during which an s-th second deposition layer having an s-th second thickness is formed while the absolute value of the calculated temperature change rate (ΔT_{S}) is less than or equal to the threshold temperature change rate (ΔT_{C}).

At the start time point, when the voltage applying device 120 in a stop state maintains the stop state by the controller 140, the absolute value of the calculated temperature change rate (ΔT_{S}) may become less than the threshold temperature change rate (ΔT_{C}). Accordingly, the maximum deposition time may be longer when forming the s-th second deposition layer than when forming the s-th first deposition layer. In an example, the controller 140 may apply the control manner described above in order to form the pre-designed s-th deposition layer. Further, in an example, the controller 140 may not set the deposition time to the maximum deposition time, and when the s-th deposition layer having the preset s-th thickness is formed, may control that the voltage applying device 120 changes to a stop state even though the absolute value of the calculated temperature change rate (ΔT_{S}) is less than the threshold temperature change rate (ΔT_{C}).

In an example, when the s-th first thickness and the s-th second thickness are identical, tₛ₂ may be less than tₛ₁. In addition, for example, when tₛ₁ and tₛ₂ are identical, the s-th second thickness may be thicker than the s-th first thickness.

In an example, after the start time point, at a finish time point when the calculated temperature change rate (ΔT_{S}) is a negative number and the absolute value of the calculated temperature change rate (ΔT_{S}) is equal to the threshold temperature change rate (ΔT_{C}), the voltage applying device 120 may be in a stop state, and the controller 140 may control that the voltage applying device 120 in the stop state maintains the stop state and then changes to an operating state. In addition, the controller 140 here may control that the voltage applying device 120 maintains the operating state until an f-th deposition layer having an f-th thickness is formed and the deposition layer DL having the final target thickness is formed while the absolute value of the calculated temperature change rate (ΔT_{S}) is equal to or less than the threshold temperature change rate (ΔT_{C}). Here, the f-th deposition layer may be a portion of the deposition layer DL and the f-th thickness may be greater than the s-th thickness. Here, the maximum deposition time in which the voltage applying device 120 may be maintained in the operating state may be until the absolute value of the calculated temperature change rate (ΔT_{S}) becomes equal to the threshold temperature change rate (ΔT_{C}), and a maximum value of the f-th thickness that is the thickness of the f-th deposition layer may be a thickness obtained when performing deposition until the absolute value of the calculated temperature change rate (ΔT_{S}) becomes equal to the threshold temperature change rate (ΔT_{C}).

In an example, at the start time point, when the controller 140 controls that the voltage applying device 120 in a stop state maintains the stop state and then changes to an operating state, the thickness of the s-th second deposition layer may be less than the thickness of the f-th deposition layer. In other words, the s-th second thickness may be less than the f-th thickness. Controlling that a thicker deposition layer is formed at the finish time point than at the start time point may help improve the quality of the deposition layer DL since the temperature of the deposition substrate 210D is at a set temperature and in a stable state with a low change rate by the temperature regulation part 150.

In an example, time t_{sf} in which the voltage applying device 120 in a stop state maintains the stop state by the controller 140 at the finish time point may be greater than time tₛₛ in which the voltage applying device 120 in a stop state maintains the stop state by the controller 140 at the start time point. Further, in an example, the absolute value of the calculated temperature change rate (ΔT_{S}) when the controller 140 at the finish time point controls that the voltage applying device 120 in a stop state maintains the stop state and then changes to an operating state may be less than the absolute value of the calculated temperature change rate (ΔT_{S}) when the controller 140 at the start time point controls that the voltage applying device 120 in a stop state maintains the stop state and then changes to an operating state. Through this, the controller 140 may control that the f-th thickness is greater than the s-th thickness (for example, the s-th first thickness and the s-th second thickness). In an example, the f-th thickness may be less than the final target thickness.

In an example, between the start time point and the finish time point, at at least one intermediate time point when the calculated temperature change rate (ΔT_{S}) is a negative number and the absolute value of the calculated temperature change rate (ΔT_{S}) is equal to the threshold temperature change rate (ΔT_{C}), the voltage applying device 120 may be in a stop state, and the controller 140 may control that the voltage applying device 120 in the stop state maintains the stop state and then changes to an operating state. In addition, the controller 140 here may control that the voltage applying device 120 maintains the operating state until an i-th deposition layer having an i-th thickness is formed while the absolute value of the calculated temperature change rate (ΔT_{S}) is equal to or less than the threshold temperature change rate (ΔT_{C}). Here, the i-th deposition layer may be a portion of the deposition layer DL.

In an example, the i-th deposition layer may be a single layer. When the i-th deposition layer is the single layer, the i-th thickness may be greater than or equal to the s-th thickness. In addition, the i-th thickness may be less than the f-th thickness. The maximum deposition time in which the voltage applying device 120 may be maintained in the operating state may be until the absolute value of the calculated temperature change rate (ΔT_{S}) becomes equal to the threshold temperature change rate (ΔT_{C}), and a maximum value of the i-th thickness that is the thickness of the i-th deposition layer may be a thickness obtained when performing deposition until the absolute value of the calculated temperature change rate (ΔT_{S}) becomes equal to the threshold temperature change rate (ΔT_{C}).

In an example, at the start time point, when the controller 140 controls that the voltage applying device 120 in a stop state maintains the stop state and then changes to an operating state, the thickness of the s-th second deposition layer may be equal to or less than the thickness of the i-th deposition layer. In other words, the s-th second thickness may be equal to or less than the i-th thickness.

In an example, time tₛᵢ in which the voltage applying device 120 in a stop state maintains the stop state by the controller 140 at the intermediate time point may be equal to or greater than time tₛₛ in which the voltage applying device 120 in a stop state maintains the stop state by the controller 140 at the start time point. In an example, time t_{sf} in which the voltage applying device 120 in a stop state maintains the stop state by the controller 140 at the finish time point may be greater than time tₛᵢ in which the voltage applying device 120 in a stop state maintains the stop state by the controller 140 at the intermediate time point.

In an example, the absolute value of the calculated temperature change rate (ΔT_{S}) when the controller 140 at the intermediate time point controls that the voltage applying device 120 in a stop state maintains the stop state and then changes to an operating state may be equal to or less than the absolute value of the calculated temperature change rate (ΔT_{S}) when the controller 140 at the start time point controls that the voltage applying device 120 in a stop state maintains the stop state and then changes to an operating state. In an example, the absolute value of the calculated temperature change rate (ΔT_{S}) when the controller 140 at the finish time point controls that the voltage applying device 120 in a stop state maintains the stop state and then changes to an operating state may be less than the absolute value of the calculated temperature change rate (ΔT_{S}) when the controller 140 at the intermediate time point controls that the voltage applying device 120 in a stop state maintains the stop state and then changes to an operating state. Through this, the controller 140 may control that the s-th second thickness is equal to the i-th thickness or less than the i-th thickness and the f-th thickness is greater than the i-th thickness.

In an example, the i-th deposition layer may be a multi-layer. In an example, the intermediate time point may include an i₁-th time point adjacent to the start time point and an i₂-th time point adjacent to the finish time point. The i₁-th time point and the i₂-th time point are merely examples, and an additional intermediate time point may be present in between. Hereinafter, the i-th deposition layer that is the multi-layer is described centering on the i₁-th time point and the i₂-th time point, and other intermediate time points may be understood with reference to the description below unless contradicted.

In an example, at the i₁-th time point and the i₂-th time point, the voltage applying device 120 may be in a stop state, and the controller 140 may control that the voltage applying device 120 in the stop state maintains the stop state and then changes to an operating state. In addition, the controller 140 here may control that the voltage applying device 120 maintains the operating state until each of an i₁-th deposition layer having an i₁-th thickness and an i₂-th deposition layer having an i₂-th thickness is formed while the absolute value of the calculated temperature change rate (ΔT_{S}) is equal to or less than the threshold temperature change rate (ΔT_{C}). Here, the i₁-th deposition layer and the i₂-th deposition layer may be a portion of the i-th deposition layer and the i₁-th thickness may be equal to the i₂-th thickness or less than the i₂-th thickness. In addition, the i₁-th thickness may be equal to the s-th thickness or greater than the s-th thickness and the i₂-th thickness may be less than the f-th thickness. Here, the maximum deposition time in which the voltage applying device 120 may be maintained in the operating state may be until the absolute value of the calculated temperature change rate (ΔT_{S}) becomes equal to the threshold temperature change rate (ΔT_{C}), and each maximum value of the i₁-th thickness that is the thickness of the i₁-th deposition layer and the i₂-th thickness that is the thickness of the i₂-th deposition layer may be each thickness obtained when performing deposition until the absolute value of the calculated temperature change rate (ΔT_{S}) becomes equal to the threshold temperature change rate (ΔT_{C}).

In an example, at the start time point, when the controller 140 controls that the voltage applying device 120 in a stop state maintains the stop state and then changes to an operating state, the thickness of the s-th second deposition layer may be equal to or less than the thickness of the i₁-th deposition layer. In other words, the s-th second thickness may be equal to or less than the i₁-th thickness.

In an example, time tₛᵢ₁ in which the voltage applying device 120 in a stop state maintains the stop state by the controller 140 at the i₁-th time point may be equal to or greater than time tₛₛ in which the voltage applying device 120 in a stop state maintains the stop state by the controller 140 at the start time point. Time tₛᵢ₂ in which the voltage applying device 120 in a stop state maintains the stop state by the controller 140 at the i₂-th time point may be equal to or greater than time tₛᵢ₁ in which the voltage applying device 120 in a stop state maintains the stop state by the controller 140 at the i₁-th time point. In an example, time t_{sf} in which the voltage applying device 120 in a stop state maintains the stop state by the controller 140 at the finish time point may be greater than time tₛᵢ₂ in which the voltage applying device 120 in a stop state maintains the stop state by the controller 140 at the i₂-th time point.

In an example, the absolute value of the calculated temperature change rate (ΔT_{S}) when the controller 140 at the i₁-th time point controls that the voltage applying device 120 in a stop state maintains the stop state and then changes to an operating state may be equal to or less than the absolute value of the calculated temperature change rate (ΔT_{S}) when the controller 140 at the start time point controls that the voltage applying device 120 in a stop state maintains the stop state and then changes to an operating state. In an example, the absolute value of the calculated temperature change rate (ΔT_{S}) when the controller 140 at the i₂-th time point controls that the voltage applying device 120 in a stop state maintains the stop state and then changes to an operating state may be equal to or less than the absolute value of the calculated temperature change rate (ΔT_{S}) when the controller 140 at the i₁-th time point controls that the voltage applying device 120 in a stop state maintains the stop state and then changes to an operating state. In an example, the absolute value of the calculated temperature change rate (ΔT_{S}) when the controller 140 at the finish time point controls that the voltage applying device 120 in a stop state maintains the stop state and then changes to an operating state may be less than the absolute value of the calculated temperature change rate (ΔT_{S}) when the controller 140 at the i₂-th time point controls that the voltage applying device 120 in a stop state maintains the stop state and then changes to an operating state. Through this, the controller 140 may control that the s-th second thickness is equal to the i₁-th thickness or less than the i₁-th thickness, may control that the i₁-th thickness is equal to the i₂-th thickness or less than the i₂-th thickness, and may control the f-th thickness is greater than the i₂-th thickness.

In an example, the deposition substrate 210D may have a flat form. As described above, in the deposition substrate 210D with the flat form, a greater thermal stress difference leads to a growth of whiskers and then a negative impact on yield, which may be minimized through the deposition process using the controller 140.

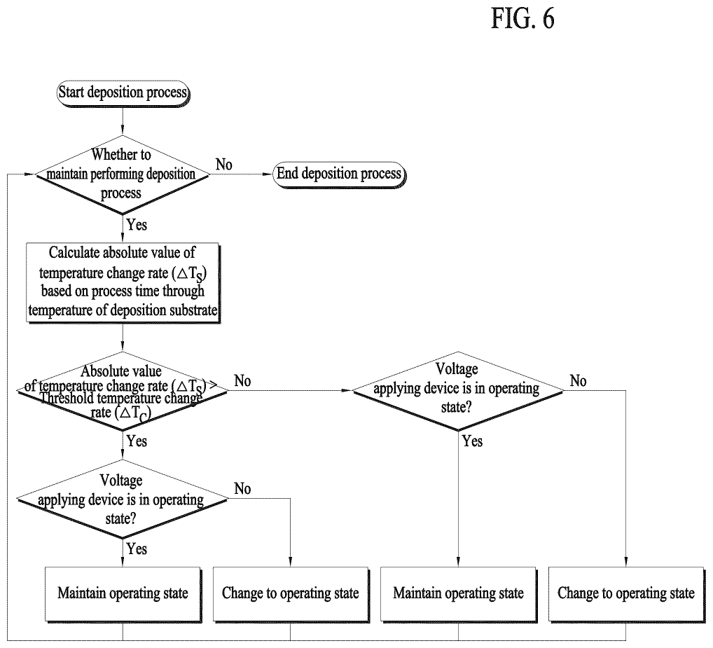

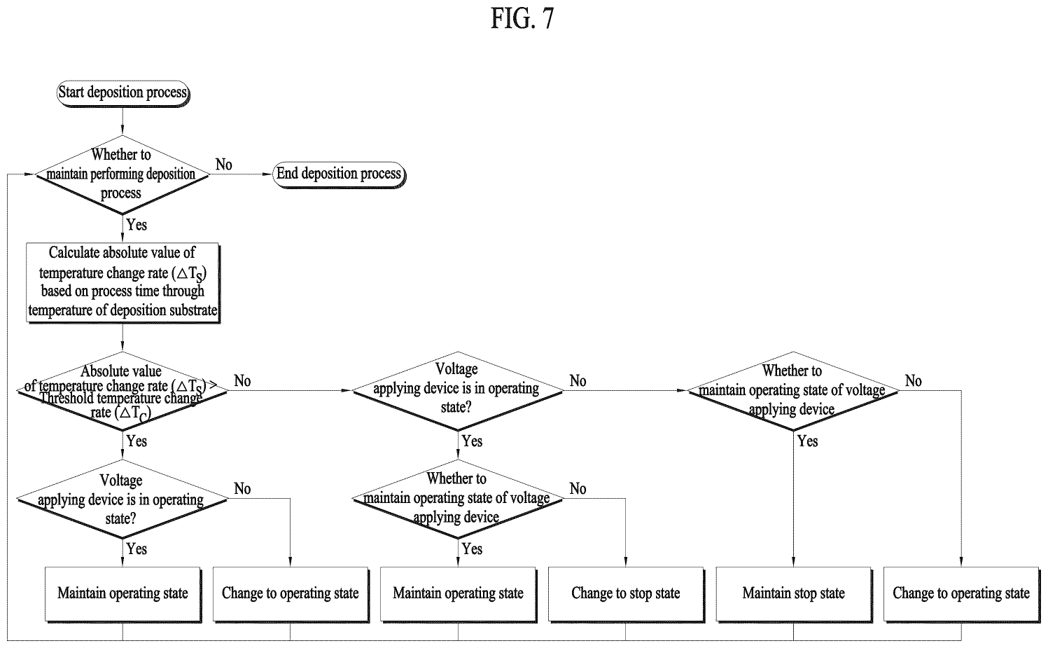

FIGS. 6 and 7 are flowcharts for illustrating a manner of performing a deposition process by the deposition apparatus 100 according to a second example embodiment of the present disclosure. In an example, the deposition substrate 210D may have a form with at least a portion bent. In this case, unlike the descriptions referring to FIGS. 2 to 5, the deposition substrate 210D of a form with at least a portion bent may be turned into a flat form using a thermal stress difference intentionally while forming the deposition layer DL. In addition, the descriptions referring to FIGS. 2 to 5 may be referenced in the description below unless contradicted.

Referring to FIG. 6, in an example, when the absolute value of the calculated temperature change rate (ΔT_{S}) is greater than the threshold temperature change rate (ΔT_{C}), the controller 140 may control that the voltage applying device 120 in an operating state changes to a stop state. In an example, when the absolute value of the calculated temperature change rate (ΔT_{S}) is greater than the threshold temperature change rate (ΔT_{C}), the controller 140 may control that the voltage applying device 120 in an operating state maintains the operating state. In an example, when the absolute value of the calculated temperature change rate (ΔT_{S}) is greater than the threshold temperature change rate (ΔT_{C}), the controller 140 may control that the voltage applying device 120 in a stop state changes to an operating state. When the deposition substrate 210D has the form with at least a portion bent, intentionally maintaining a state (in other words, a state in which the absolute value of the calculated temperature change rate (ΔT_{S}) is greater than the threshold temperature change rate (ΔT_{C})) in which a thermal stress difference is large may help turn the deposition substrate 210D into a flat form while forming the deposition layer DL.

Referring to FIG. 7, in an example, when the absolute value of the calculated temperature change rate (ΔT_{S}) is equal to the threshold temperature change rate (ΔT_{C}) or less than the threshold temperature change rate (ΔT_{C}), the controller 140 may control that the voltage applying device 120 in a stop state maintains the stop state or changes to an operating state. Further, in an example, when the absolute value of the calculated temperature change rate (ΔT_{S}) is equal to the threshold temperature change rate (ΔT_{C}) or less than the threshold temperature change rate (ΔT_{C}), the controller 140 may control that the voltage applying device 120 in an operating state maintains the operating state or changes to a stop state.

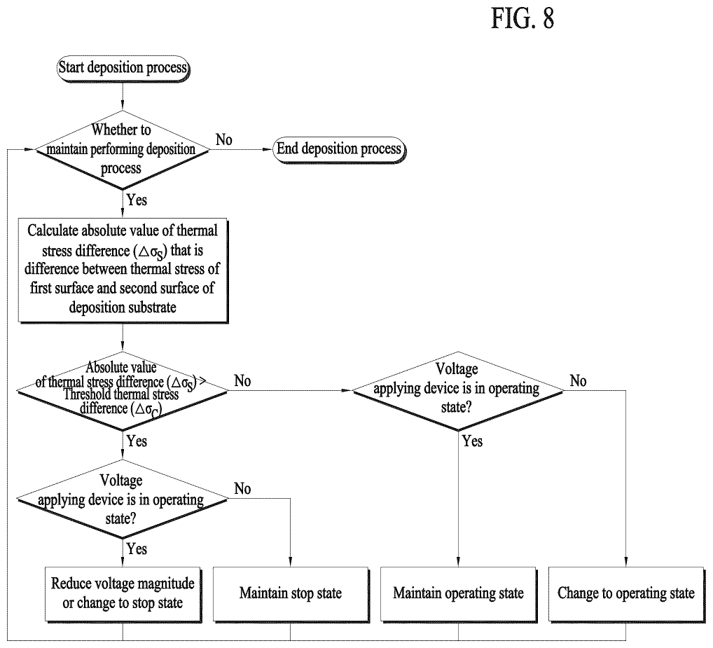

FIGS. 8 to 11 are flowcharts for illustrating a manner of performing a deposition process by the deposition apparatus 100 according to a third example embodiment of the present disclosure. The descriptions referring to FIGS. 2 to 5 may be referenced in the description below unless contradicted.

In an example, the controller 140 may calculate thermal stress of a first surface DL-1 of the deposition layer DL in contact with the deposition substrate 210D and thermal stress of a second surface DL-2 opposite to the first surface DL-1 by the temperature of the deposition substrate 210D measured in the temperature measurement part 130 (see FIG. 1). In the present disclosure, thermal stress may be calculated through a simulation program or the like based on the temperature of the deposition substrate 210D measured in the temperature measurement part 130. Specifically, in an example, supposing that a temperature of the first surface DL-1 in contact with the deposition substrate 210D is equal to the temperature of the deposition substrate 210D measured in the temperature measurement part 130, the controller 140 may calculate the thermal stress of the first surface DL-1 by properties (for example, elastic modulus, coefficient of thermal expansion, and yield stress) of the deposition layer DL per se. Here, elastic modulus, coefficient of thermal expansion, and yield stress may be previously inputted, or a value obtained from a simulation program may be used. Alternatively, in an example, supposing that a temperature of the second surface DL-2 is equal to a correction temperature that is corrected by the thickness of the deposition layer DL and a temperature of the deposition process space 110S when calculating the thermal stress based on the temperature of the deposition substrate 210D measured in the temperature measurement part 130, the controller 140 may calculate the thermal stress of the second surface DL-2 by properties (for example, elastic modulus, coefficient of thermal expansion, and yield stress) of the deposition layer DL per se. The temperature of the deposition process space 110S may be measured by a micro-electromechanical systems (MEMS) sensor or the like through the through hole (not shown) formed in the chamber 110 but is not limited thereto.

In an example, the controller 140 may calculate a thermal stress difference (Δσ_{S}) that is a difference between the thermal stress of the first surface DL-1 and the thermal stress of the second surface DL-2. In addition, the controller 140 may calculate an absolute value of the thermal stress difference (Δσ_{S}).

In an example, the controller 140 may compare the absolute value of the calculated thermal stress difference (Δσ_{S}) and a preset threshold thermal stress difference (Δσ_{C}) and control operation of the voltage applying device 120. The threshold thermal stress difference (Δσ_{C}) may be set to any design value. Depending on the threshold thermal stress difference (Δσ_{C}), a process speed or a quality of the deposition layer DL may vary. In an example, the threshold thermal stress difference (Δσ_{C}) may be set to a suitable value obtained through a simulation program or the like based thereon.

Referring to FIG. 8, in an example, when the absolute value of the calculated thermal stress difference (Δσ_{S}) is greater than the threshold thermal stress difference (Δσ_{C}), the controller 140 may control that the voltage applying device 120 in an operating state applies a voltage with a magnitude reduced or changes to a stop state. When the magnitude of the voltage applied by the voltage applying device 120 is reduced, deposition speed may decrease. In an example, when the absolute value of the calculated thermal stress difference (Δσ_{S}) is greater than the threshold thermal stress difference (Δσ_{C}), the controller 140 may control that the voltage applying device 120 in a stop state maintains the stop state. In an example, when the absolute value of the calculated thermal stress difference (Δσ_{S}) is equal to the threshold thermal stress difference (Δσ_{C}) or less than the threshold thermal stress difference (Δσ_{C}), the controller 140 may control that the voltage applying device 120 in a stop state changes to an operating state. In an example, when the absolute value of the calculated thermal stress difference (Δσ_{S}) is equal to the threshold thermal stress difference (Δσ_{C}) or less than the threshold thermal stress difference (Δσ_{C}), the controller 140 may control that the voltage applying device 120 in an operating state maintains the operating state. Then, the controller 140 may re-determine whether to maintain performing the deposition process and control that the control manner described above is repeated or the deposition process is finished.

In an example, as the controller 140 controls the deposition process as described above, the generation and growth of whiskers may be minimized, which may improve yield reduction.

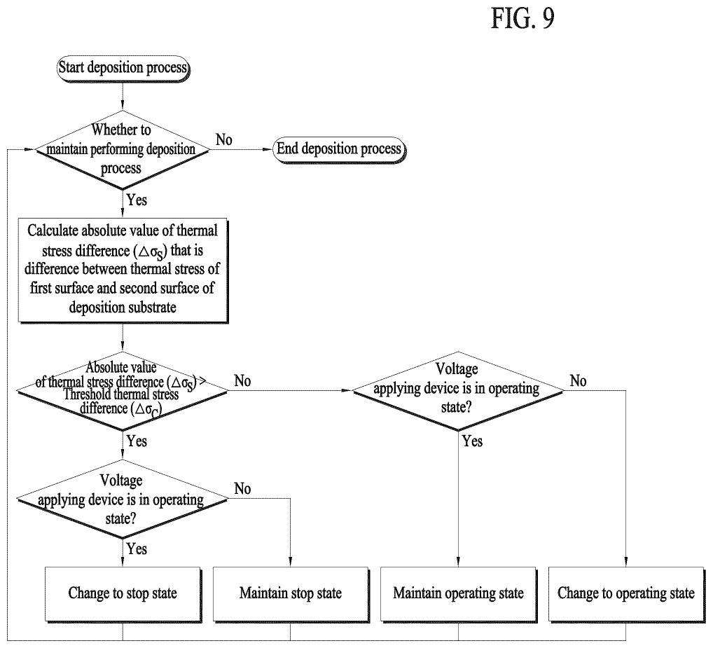

Referring to FIG. 9, in an example, when the absolute value of the calculated thermal stress difference (Δσ_{S}) is greater than the threshold thermal stress difference (Δσ_{C}), the controller 140 may control that the voltage applying device 120 in an operating state changes to a stop state. In other words, the controller 140 here may control that the voltage applying device 120 in the operating state directly changes to the stop state without reducing the magnitude of a voltage applied as in FIG. 8. The controller 140 controlling in this on-off manner may help secure uniformity in the deposition layer DL.

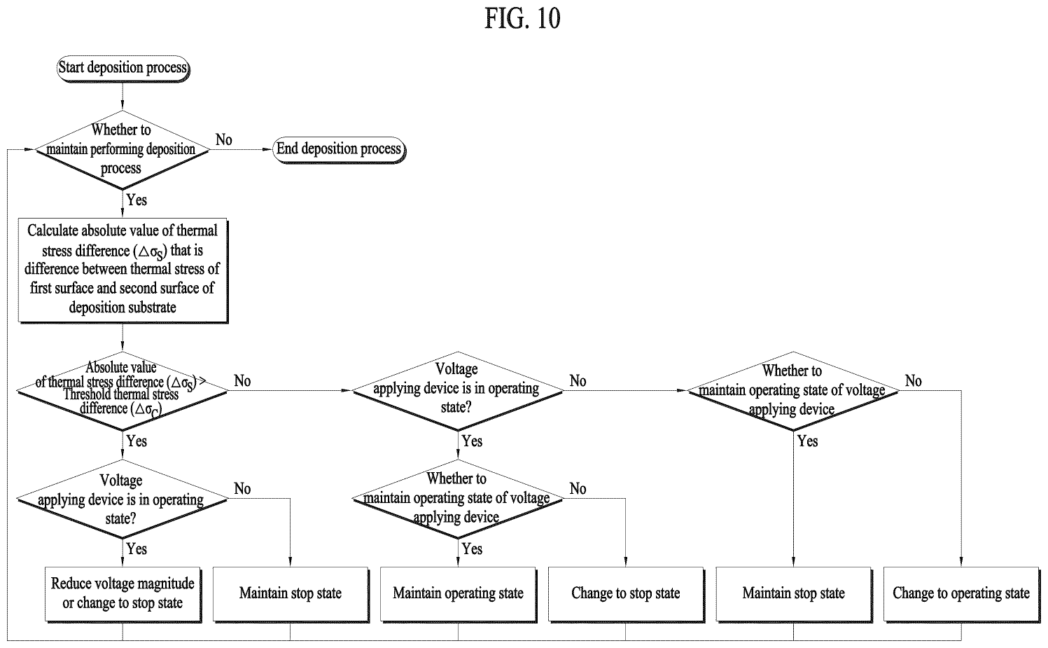

Referring to FIG. 10, in an example, when the absolute value of the calculated thermal stress difference (Δσ_{S}) is greater than the threshold thermal stress difference (Δσ_{C}), the controller 140 may control that the voltage applying device 120 in an operating state applies a voltage with a magnitude reduced or changes to a stop state. In an example, when the absolute value of the calculated thermal stress difference (Δσ_{S}) is greater than the threshold thermal stress difference (Acc), the controller 140 may control that the voltage applying device 120 in a stop state maintains the stop state. In an example, when the absolute value of the calculated thermal stress difference (Δσ_{S}) is equal to the threshold thermal stress difference (Δσ_{C}) or less than the threshold thermal stress difference (Δσ_{C}), the controller 140 may control that the voltage applying device 120 in a stop state maintains the stop state or changes to an operating state. Further, in an example, when the absolute value of the calculated thermal stress difference (Δσ_{S}) is equal to the threshold thermal stress difference (Δσ_{C}) or less than the threshold thermal stress difference (Δσ_{C}), the controller 140 may control that the voltage applying device 120 in an operating state maintains the operating state or changes to a stop state. Then, the controller 140 may re-determine whether to maintain performing the deposition process and control that the control manner described above is repeated or the deposition process is finished.

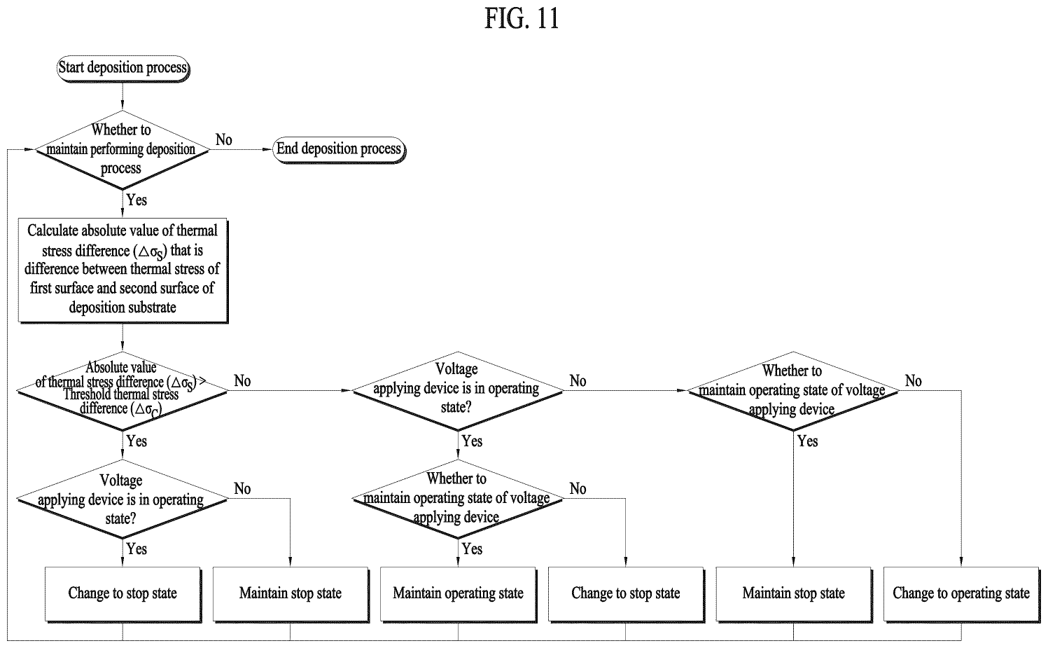

Referring to FIG. 11, in an example, when the absolute value of the calculated thermal stress difference (Δσ_{S}) is greater than the threshold thermal stress difference (Δσ_{C}), the controller 140 may control that the voltage applying device 120 in an operating state changes to a stop state. In other words, the controller 140 here may control that the voltage applying device 120 in the operating state directly changes to the stop state without reducing the magnitude of a voltage applied as in FIG. 10. The controller 140 controlling in this on-off manner may help secure uniformity in the deposition layer DL.

In an example, the controller 140 may perform a plurality of deposition processes and form the deposition layer DL that has the final target thickness. Performing the plurality of deposition processes may minimize shear stress excessively applied or unevenly applied to the formed deposition layer DL, enhance film quality, and help secure economic effectiveness in the processes.

In an example, as described above, the controller 140 may start performing the deposition process when the deposition layer DL is not formed. In this case, since a temperature rise rate of the deposition substrate 210D by the temperature regulation part 150 is high, the absolute value of the calculated thermal stress difference (Δσ_{S}) may be greater than the preset threshold thermal stress difference (Δσ_{C}). As the process time increases, the temperature of the deposition substrate 210D may be gradually stabilized and the temperature rise rate may be gradually decreased. In other words, the absolute value of the calculated thermal stress difference (Δσ_{S}) may gradually decrease, and a start time point may be reached at which the calculated thermal stress difference (Δσ_{S}) is a negative number and the absolute value of the calculated thermal stress difference (Δσ_{S}) is first equal to the threshold thermal stress difference (Δσ_{C}).

In an example, at the start time point when the absolute value of the calculated thermal stress difference (Δσ_{S}) is equal to the threshold thermal stress difference (Δσ_{C}), the voltage applying device 120 may be in a stop state. In addition, before the start time point, the voltage applying device 120 may be in the stop state. Specifically, in an example, the controller 140 may control that the voltage applying device 120 maintains the stop state before the start time point.

In an example, the controller 140 may control that the voltage applying device 120 in the stop state changes to an operating state. When the voltage applying device 120 operates, the deposition layer DL may be formed on the deposition substrate 210D.

In an example, the controller 140 may control that the voltage applying device 120 in the stop state maintains the stop state and then changes to the operating state. When the voltage applying device 120 operates, the deposition layer DL may be formed on the deposition substrate 210D.

In an example, the controller 140 may control that the voltage applying device 120 maintains the operating state until an s-th deposition layer having an s-th thickness is formed while the absolute value of the calculated thermal stress difference (Δσ_{S}) is equal to or less than the threshold thermal stress difference (Δσ_{C}). Here, the s-th deposition layer may be a portion of the deposition layer DL and the s-th thickness may be less than the final target thickness. In an example, when the controller 140 may control that the voltage applying device 120 changes to the operating state, the deposition layer DL may be formed and the temperature of the deposition substrate 210D may rise, which may lead to a gradual rise in the absolute value of the calculated thermal stress difference (Δσ_{S}). Here, a maximum deposition time in which the voltage applying device 120 may be maintained in the operating state may be until the absolute value of the calculated thermal stress difference (Δσ_{S}) becomes equal to the threshold thermal stress difference (Δσ_{C}). In other words, a maximum value of the s-th thickness that is the thickness of the s-th deposition layer may be a thickness obtained when performing deposition until the absolute value of the calculated thermal stress difference (Δσ_{S}) becomes equal to the threshold thermal stress difference (Δσ_{C}).

In an example, the controller 140 may control that the voltage applying device 120 in a stop state changes to an operating state (in other words, directly changes to the operating state without maintaining the stop state), and in this case, the voltage applying device 120 may operate for time tₛ₁ during which an s-th first deposition layer having an s-th first thickness is formed while the absolute value of the calculated thermal stress difference (Δσ_{S}) is less than or equal to the threshold thermal stress difference (Δσ_{C}). Further, in an example, the controller 140 may control that the voltage applying device 120 in a stop state maintains the stop state and then changes to an operating state, and in this case, the voltage applying device 120 may operate for time tₛ₂ during which an s-th second deposition layer having an s-th second thickness is formed while the absolute value of the calculated thermal stress difference (As) is less than or equal to the threshold thermal stress difference (Δσ_{C}).

At the start time point, when the voltage applying device 120 in a stop state maintains the stop state by the controller 140, the absolute value of the calculated thermal stress difference (Δσ_{S}) may become less than the threshold thermal stress difference (Δσ_{C}). Accordingly, the maximum deposition time may be longer when forming the s-th second deposition layer than when forming the s-th first deposition layer. In an example, the controller 140 may apply the control manner described above in order to form the pre-designed s-th deposition layer. Further, in an example, the controller 140 may not set the deposition time to the maximum deposition time, and when the s-th deposition layer having the preset s-th thickness is formed, may control that the voltage applying device 120 changes to a stop state even though the absolute value of the calculated thermal stress difference (Δσ_{S}) is less than the threshold thermal stress difference (Δσ_{C}).

In an example, when the s-th first thickness and the s-th second thickness are identical, tₛ₂ may be less than tₛ₁. In addition, for example, when tₛ₁ and tₛ₂ are identical, the s-th second thickness may be thicker than the s-th first thickness.

In an example, after the start time point, at a finish time point when the calculated thermal stress difference (Δσ_{S}) is a negative number and the absolute value of the calculated thermal stress difference (Δσ_{S}) is equal to the threshold thermal stress difference (Δσ_{C}), the voltage applying device 120 may be in a stop state, and the controller 140 may control that the voltage applying device 120 in the stop state maintains the stop state and then changes to an operating state. In addition, the controller 140 here may control that the voltage applying device 120 maintains the operating state until an f-th deposition layer having an f-th thickness is formed and the deposition layer DL having the final target thickness is formed while the absolute value of the calculated thermal stress difference (Δσ_{S}) is equal to or less than the threshold thermal stress difference (Δσ_{C}). Here, the f-th deposition layer may be a portion of the deposition layer DL and the f-th thickness may be greater than the s-th thickness. In an example, the f-th thickness may be less than the final target thickness. Here, the maximum deposition time in which the voltage applying device 120 may be maintained in the operating state may be until the absolute value of the calculated thermal stress difference (Δσ_{S}) becomes equal to the threshold thermal stress difference (Δσ_{C}), and a maximum value of the f-th thickness that is the thickness of the f-th deposition layer may be a thickness obtained when performing deposition until the absolute value of the calculated thermal stress difference (Δσ_{S}) becomes equal to the threshold thermal stress difference (Δσ_{C}).

In an example, at the start time point, when the controller 140 controls that the voltage applying device 120 in a stop state maintains the stop state and then changes to an operating state, the thickness of the s-th second deposition layer may be less than the thickness of the f-th deposition layer. In other words, the s-th second thickness may be less than the f-th thickness. Controlling that a thicker deposition layer is formed at the finish time point than at the start time point may help improve the quality of the deposition layer DL since the temperature of the deposition substrate 210D is at a set temperature and in a stable state with a low change rate by the temperature regulation part 150.

In an example, time t_{sf} in which the voltage applying device 120 in a stop state maintains the stop state by the controller 140 at the finish time point may be greater than time tₛₛ in which the voltage applying device 120 in a stop state maintains the stop state by the controller 140 at the start time point. Further, in an example, the absolute value of the calculated thermal stress difference (Δσ_{S}) when the controller 140 at the finish time point controls that the voltage applying device 120 in a stop state maintains the stop state and then changes to an operating state may be less than the absolute value of the calculated thermal stress difference (Δσ_{S}) when the controller 140 at the start time point controls that the voltage applying device 120 in a stop state maintains the stop state and then changes to an operating state. Through this, the controller 140 may control that the f-th thickness is greater than the s-th thickness (for example, the s-th first thickness and the s-th second thickness).

In an example, between the start time point and the finish time point, at at least one intermediate time point when the calculated thermal stress difference (Δσ_{S}) is a negative number and the absolute value of the calculated thermal stress difference (Δσ_{S}) is equal to the threshold thermal stress difference (Δσ_{C}), the voltage applying device 120 may be in a stop state, and the controller 140 may control that the voltage applying device 120 in the stop state maintains the stop state and then changes to an operating state. In addition, the controller 140 here may control that the voltage applying device 120 maintains the operating state until an i-th deposition layer having an i-th thickness is formed while the absolute value of the calculated thermal stress difference (Δσ_{S}) is equal to or less than the threshold thermal stress difference (Δσ_{C}). Here, the i-th deposition layer may be a portion of the deposition layer DL.

In an example, the i-th deposition layer may be a single layer. When the i-th deposition layer is the single layer, the i-th thickness may be greater than or equal to the s-th thickness. In addition, the i-th thickness may be less than the f-th thickness. The maximum deposition time in which the voltage applying device 120 may be maintained in the operating state may be until the absolute value of the calculated thermal stress difference (Δσ_{S}) becomes equal to the threshold thermal stress difference (Δσ_{C}), and a maximum value of the i-th thickness that is the thickness of the i-th deposition layer may be a thickness obtained when performing deposition until the absolute value of the calculated thermal stress difference (Δσ_{S}) becomes equal to the threshold thermal stress difference (Δσ_{C}).

In an example, at the start time point, when the controller 140 controls that the voltage applying device 120 in a stop state maintains the stop state and then changes to an operating state, the thickness of the s-th second deposition layer may be equal to or less than the thickness of the i-th deposition layer. In other words, the s-th second thickness may be equal to or less than the i-th thickness.

In an example, time tₛᵢ in which the voltage applying device 120 in a stop state maintains the stop state by the controller 140 at the intermediate time point may be equal to or greater than time tₛₛ in which the voltage applying device 120 in a stop state maintains the stop state by the controller 140 at the start time point. In an example, time t_{sf} in which the voltage applying device 120 in a stop state maintains the stop state by the controller 140 at the finish time point may be greater than time tₛᵢ in which the voltage applying device 120 in a stop state maintains the stop state by the controller 140 at the intermediate time point.

In an example, the absolute value of the calculated thermal stress difference (Δσ_{S}) when the controller 140 at the intermediate time point controls that the voltage applying device 120 in a stop state maintains the stop state and then changes to an operating state may be less than the absolute value of the calculated thermal stress difference (Δσ_{S}) when the controller 140 at the start time point controls that the voltage applying device 120 in a stop state maintains the stop state and then changes to an operating state. In an example, the absolute value of the calculated thermal stress difference (Δσ_{S}) when the controller 140 at the finish time point controls that the voltage applying device 120 in a stop state maintains the stop state and then changes to an operating state may be less than the absolute value of the calculated thermal stress difference (Δσ_{S}) when the controller 140 at the intermediate time point controls that the voltage applying device 120 in a stop state maintains the stop state and then changes to an operating state. Through this, the controller 140 may control that the s-th second thickness is equal to the i-th thickness or less than the i-th thickness and the f-th thickness is greater than the i-th thickness.

In an example, the i-th deposition layer may be a multi-layer. In an example, the intermediate time point may include an i₁-th time point adjacent to the start time point and an i₂-th time point adjacent to the finish time point. The i₁-th time point and the i₂-th time point are merely examples, and an additional intermediate time point may be present in between. Hereinafter, the i-th deposition layer that is the multi-layer is described centering on the i₁-th time point and the i₂-th time point, and other intermediate time points may be understood with reference to the description below unless contradicted.

In an example, at the i₁-th time point and the i₂-th time point, the voltage applying device 120 may be in a stop state, and the controller 140 may control that the voltage applying device 120 in the stop state maintains the stop state and then changes to an operating state. In addition, the controller 140 here may control that the voltage applying device 120 maintains the operating state until each of an i₁-th deposition layer having an i₁-th thickness and an i₂-th deposition layer having an i₂-th thickness is formed while the absolute value of the calculated thermal stress difference (Δσ_{S}) is equal to or less than the threshold thermal stress difference (Δσ_{C}). Here, the i₁-th deposition layer and the i₂-th deposition layer may be a portion of the i- th deposition layer and the i₁-th thickness may be equal to the i₂-th thickness or less than the i₂-th thickness. In addition, the i₁-th thickness may be equal to the s-th thickness or greater than the s-th thickness and the i₂-th thickness may be less than the f-th thickness. Here, the maximum deposition time in which the voltage applying device 120 may be maintained in the operating state may be until the absolute value of the calculated thermal stress difference (Δσ_{S}) becomes equal to the threshold thermal stress difference (Δσ_{C}), and each maximum value of the i₁-th thickness that is the thickness of the i₁-th deposition layer and the i₂-th thickness that is the thickness of the i₂-th deposition layer may be each thickness obtained when performing deposition until the absolute value of the calculated thermal stress difference (Δσ_{S}) becomes equal to the threshold thermal stress difference (Δσ_{C}).

In an example, at the start time point, when the controller 140 controls that the voltage applying device 120 in a stop state maintains the stop state and then changes to an operating state, the thickness of the s-th second deposition layer may be equal to or less than the thickness of the i₁-th deposition layer. In other words, the s-th second thickness may be equal to or less than the i₁-th thickness.

In an example, time tₛᵢ₁ in which the voltage applying device 120 in a stop state maintains the stop state by the controller 140 at the i₁-th time point may be equal to or greater than time tₛₛ in which the voltage applying device 120 in a stop state maintains the stop state by the controller 140 at the start time point. Time tₛᵢ₂ in which the voltage applying device 120 in a stop state maintains the stop state by the controller 140 at the i₂-th time point may be equal to or greater than time tₛᵢ₁ in which the voltage applying device 120 in a stop state maintains the stop state by the controller 140 at the i₁-th time point. In an example, time t_{sf} in which the voltage applying device 120 in a stop state maintains the stop state by the controller 140 at the finish time point may be greater than time tₛᵢ₂ in which the voltage applying device 120 in a stop state maintains the stop state by the controller 140 at the i₂-th time point.

In an example, the absolute value of the calculated thermal stress difference (Δσ_{S}) when the controller 140 at the i₁-th time point controls that the voltage applying device 120 in a stop state maintains the stop state and then changes to an operating state may be equal to or less than the absolute value of the calculated thermal stress difference (Δσ_{S}) when the controller 140 at the start time point controls that the voltage applying device 120 in a stop state maintains the stop state and then changes to an operating state. In an example, the absolute value of the calculated thermal stress difference (Δσ_{S}) when the controller 140 at the i₂-th time point controls that the voltage applying device 120 in a stop state maintains the stop state and then changes to an operating state may be equal to or less than the absolute value of the calculated thermal stress difference (Δσ_{S}) when the controller 140 at the i₁-th time point controls that the voltage applying device 120 in a stop state maintains the stop state and then changes to an operating state. In an example, the absolute value of the calculated thermal stress difference (Δσ_{S}) when the controller 140 at the finish time point controls that the voltage applying device 120 in a stop state maintains the stop state and then changes to an operating state may be less than the absolute value of the calculated thermal stress difference (Δσ_{S}) when the controller 140 at the i₂-th time point controls that the voltage applying device 120 in a stop state maintains the stop state and then changes to an operating state. Through this, the controller 140 may control that the s-th second thickness is equal to the i₁-th thickness or less than the i₁-th thickness, may control that the i₁-th thickness is equal to the i₂-th thickness or less than the i₂-th thickness, and may control the f-th thickness is greater than the i₂-th thickness.

In an example, the deposition substrate 210D may have a flat form. As described above, in the deposition substrate 210D with the flat form, a greater thermal stress difference leads to a growth of whiskers and then a negative impact on yield, which may be minimized through the deposition process using the controller 140.

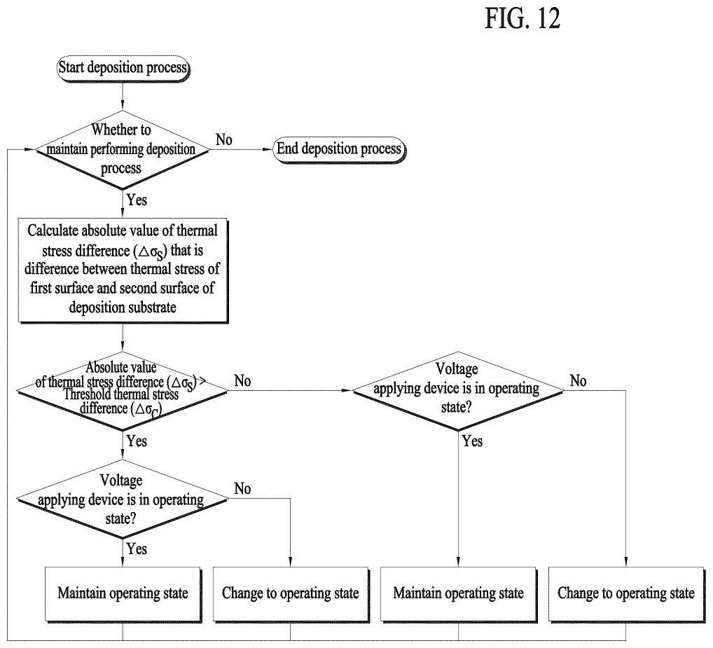

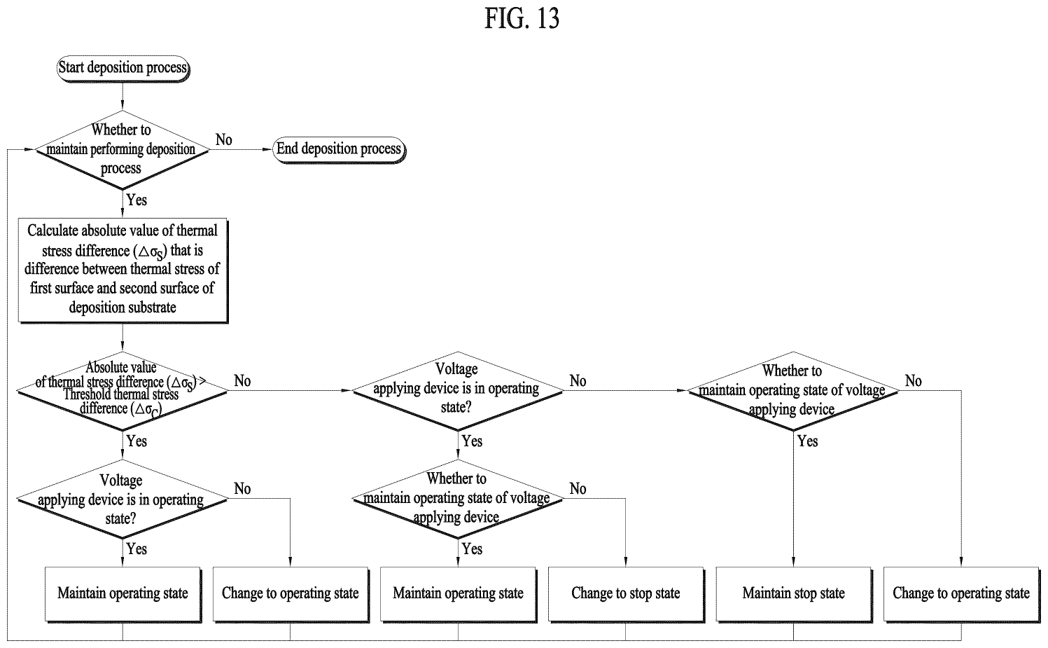

FIGS. 12 and 13 are flowcharts for illustrating a manner of performing a deposition process by the deposition apparatus 100 according to a fourth example embodiment of the present disclosure. In an example, the deposition substrate 210D may have a form with at least a portion bent. In this case, unlike the descriptions referring to FIGS. 8 to 11, the deposition substrate 210D of a form with at least a portion bent may be turned into a flat form using a thermal stress difference intentionally while forming the deposition layer DL. In addition, the descriptions referring to FIGS. 8 to 11 and the descriptions referring to FIGS. 6 and 7 may be referenced in the description below unless contradicted.

Referring to FIG. 12, in an example, when the absolute value of the calculated thermal stress difference (Δσ_{S}) is greater than the threshold thermal stress difference (Δσ_{C}), the controller 140 may control that the voltage applying device 120 in an operating state changes to a stop state. In an example, when the absolute value of the calculated thermal stress difference (Δσ_{S}) is greater than the threshold thermal stress difference (Acc), the controller 140 may control that the voltage applying device 120 in an operating state maintains the operating state. In an example, when the absolute value of the calculated thermal stress difference (Δσ_{S}) is greater than the threshold thermal stress difference (Δσ_{C}), the controller 140 may control that the voltage applying device 120 in a stop state changes to an operating state. When the deposition substrate 210D has the form with at least a portion bent, intentionally maintaining a state (in other words, a state in which the absolute value of the calculated thermal stress difference (Δσ_{S}) is greater than the threshold thermal stress difference (Δσ_{C})) in which a thermal stress difference is large may help turn the deposition substrate 210D into a flat form while forming the deposition layer DL.

Referring to FIG. 13, in an example, when the absolute value of the calculated thermal stress difference (Δσ_{S}) is equal to the threshold thermal stress difference (Δσ_{C}) or less than the threshold thermal stress difference (Δσ_{C}), the controller 140 may control that the voltage applying device 120 in a stop state maintains the stop state or changes to an operating state. Further, in an example, when the absolute value of the calculated thermal stress difference (Δσ_{S}) is equal to the threshold thermal stress difference (Δσ_{C}) or less than the threshold thermal stress difference (Δσ_{C}), the controller 140 may control that the voltage applying device 120 in an operating state maintains the operating state or changes to a stop state.

While example embodiments of the present disclosure are described above with reference to the appended drawings, the present disclosure is not limited to the example embodiments and may be implemented in various different forms, and it will be apparent to those of ordinary skill in the art to which the present disclosure pertains that other specific forms may be implemented without changing the technical spirit and essential features of the present disclosure. Therefore, the example embodiments described above are exemplary in every aspect and not to be construed as limited.

What is claimed is:

1. A deposition apparatus comprising:
a chamber configured to accommodate a target substrate that is configured to discharge a target material, a deposition substrate on which a deposition layer including the target material is formed, and an electrode substrate in contact with the deposition substrate;
a voltage applying device configured to apply a voltage to the target substrate and the electrode substrate;
a temperature measurement part configured to measure a temperature of the deposition substrate; and
a controller configured to calculate at least one of a temperature change rate and an absolute value of the temperature change rate based on a process time through the temperature of the deposition substrate measured in the temperature measurement part, compare the absolute value of the calculated temperature change rate and a preset threshold temperature change rate, control operation of the voltage applying device, and perform a deposition process for forming the deposition layer.

2. The deposition apparatus of claim 1, wherein the controller is configured to:
when the absolute value of the calculated temperature change rate is greater than the preset threshold temperature change rate, control that the voltage applying device in an operating state applies a voltage with a magnitude reduced or changes to a stop state, or control that the voltage applying device in the stop state maintains the stop state; and
when the absolute value of the calculated temperature change rate is equal to or less than the preset threshold temperature change rate, control that the voltage applying device in the stop state changes to the operating state, or control that the voltage applying device in the operating state maintains the operating state.

3. The deposition apparatus of claim 2, wherein the controller is configured to, when the absolute value of the calculated temperature change rate is greater than the preset threshold temperature change rate, control that the voltage applying device in the operating state changes to the stop state.

4. The deposition apparatus of claim 1, wherein the controller is configured to:
when the absolute value of the calculated temperature change rate is greater than the preset threshold temperature change rate, control that the voltage applying device in the operating state applies a voltage with a magnitude reduced or changes to the stop state, or control that the voltage applying device in the stop state maintains the stop state; and
when the absolute value of the calculated temperature change rate is equal to or less than the preset threshold temperature change rate, control that the voltage applying device in the stop state maintains the stop state or changes to the operating state, or control that the voltage applying device in the operating state maintains the operating state or changes to the stop state.

5. The deposition apparatus of claim 4, wherein the controller is configured to, when the absolute value of the calculated temperature change rate is greater than the preset threshold temperature change rate, control that the voltage applying device in the operating state changes to the stop state.

6. The deposition apparatus of claim 4, wherein the controller is configured to perform a plurality of deposition processes and form the deposition layer having a final target thickness.

7. The deposition apparatus of claim 6, wherein, at a start time point when the absolute value of the calculated temperature change rate is equal to the preset threshold temperature change rate, the voltage applying device is in the stop state,
wherein the controller is configured to control that the voltage applying device in the stop state changes to the operating state, or control that the voltage applying device in the stop state maintains the stop state and then changes to the operating state and control that the voltage applying device maintains the operating state until an s-th deposition layer having an s-th thickness is formed while the absolute value of the calculated temperature change rate is equal to or less than the preset threshold temperature change rate, and
wherein the s-th deposition layer is a portion of the deposition layer and the s-th thickness is less than the final target thickness.

8. The deposition apparatus of claim 7, wherein, after the start time point, at a finish time point when the calculated temperature change rate is a negative number and the absolute value of the calculated temperature change rate is equal to the preset threshold temperature change rate, the voltage applying device is in the stop state,
wherein the controller is configured to control that the voltage applying device in the stop state maintains the stop state and then changes to the operating state and control that the voltage applying device maintains the operating state until an f-th deposition layer having an f-th thickness is formed and the deposition layer having the final target thickness is formed while the absolute value of the calculated temperature change rate is equal to or less than the preset threshold temperature change rate, and
wherein the f-th deposition layer is a portion of the deposition layer and the f-th thickness is greater than the s-th thickness.

9. The deposition apparatus of claim 8, wherein, between the start time point and the finish time point, at at least one intermediate time point when the calculated temperature change rate is a negative number and the absolute value of the calculated temperature change rate is equal to the preset threshold temperature change rate, the voltage applying device is in the stop state,
wherein the controller is configured to control that the voltage applying device in the stop state maintains the stop state and then changes to the operating state and control that the voltage applying device maintains the operating state until an i-th deposition layer having an i-th thickness is formed while the absolute value of the calculated temperature change rate is equal to or less than the preset threshold temperature change rate, and
wherein the i-th deposition layer is a portion of the deposition layer.

10. The deposition apparatus of claim 9, wherein the at least one intermediate time point includes an i₁-th time point adjacent to the start time point and an i₂-th time point adjacent to the finish time point,
wherein the controller is configured to control that the voltage applying device in the stop state at the i₁-th time point and the i₂-th time point maintains the stop state and then changes to the operating state and control that the voltage applying device maintains the operating state until each of an i₁-th deposition layer having an i₁-th thickness and an i₂-th deposition layer having an i₂-th thickness is formed while the absolute value of the calculated temperature change rate is equal to or less than the preset threshold temperature change rate, and
wherein the i₁-th deposition layer and the i₂-th deposition layer are a portion of the i-th deposition layer and the i₁-th thickness is equal to the i₂-th thickness or less than the i₂-th thickness.

11. The deposition apparatus of claim 10, wherein the i₁-th thickness is equal to the s-th thickness or greater than the s-th thickness, and
wherein the i₂-th thickness is less than the f-th thickness.

12. The deposition apparatus of claim 1, wherein the deposition substrate has a flat form.

13. The deposition apparatus of claim 1, wherein the deposition substrate has a form with at least a portion bent, and
wherein the controller is configured to, when the absolute value of the calculated temperature change rate is greater than the preset threshold temperature change rate, control that the voltage applying device in the operating state maintains the operating state or control that the voltage applying device in the stop state changes to the operating state.

14. The deposition apparatus of claim 1, wherein the preset threshold temperature change rate is less than or equal to an arithmetic average of a highest temperature (T_{f}) of the deposition substrate and a lowest temperature (Tᵢ) of the deposition substrate which are measured in the temperature measurement part.

15. A deposition apparatus comprising:
a chamber configured to accommodate a target substrate that is configured to discharge a target material, a deposition substrate on which a deposition layer including the target material is formed, and an electrode substrate in contact with the deposition substrate;
a voltage applying device configured to apply a voltage between the target substrate and the electrode substrate;
a temperature measurement part configured to measure a temperature of the deposition substrate; and
a controller configured to calculate thermal stress of a first surface of the deposition layer in contact with the deposition substrate and thermal stress of a second surface opposite to the first surface by the temperature of the deposition substrate measured in the temperature measurement part, calculate a thermal stress difference that is a difference between the thermal stress of the first surface and the thermal stress of the second surface, compare an absolute value of the thermal stress difference and a preset threshold thermal stress difference, control operation of the voltage applying device, and perform a deposition process for forming the deposition layer.

16. The deposition apparatus of claim 15, wherein the controller is configured to:
when the absolute value of the calculated thermal stress difference is greater than the preset threshold thermal stress difference, control that the voltage applying device in an operating state changes to a stop state, or control that the voltage applying device in the stop state maintains the stop state; and
when the absolute value of the calculated thermal stress difference is equal to or less than the preset threshold thermal stress difference, control that the voltage applying device in the stop state changes to the operating state, or control that the voltage applying device in the operating state maintains the operating state.

17. The deposition apparatus of claim 15, wherein the voltage applying device is configured to apply a direct current (DC) voltage and apply a negative voltage to the target substrate and a positive voltage to the electrode substrate.

18. The deposition apparatus of claim 15, wherein the controller is configured to:
when the absolute value of the calculated thermal stress difference is greater than the preset threshold thermal stress difference, control that the voltage applying device in the operating state changes to the stop state, or control that the voltage applying device in the stop state maintains the stop state; and
when the absolute value of the calculated thermal stress difference is equal to or less than the preset threshold thermal stress difference, control that the voltage applying device in the stop state maintains the stop state or changes to the operating state, or control that the voltage applying device in the operating state maintains the operating state or changes to the stop state.

19. The deposition apparatus of claim 15, wherein the deposition substrate has a form with at least a portion bent, and
wherein the controller is configured to, when the absolute value of the calculated thermal stress difference is greater than the preset threshold thermal stress difference, control that the voltage applying device in the operating state maintains the operating state, or control that the voltage applying device in the stop state changes to the operating state.

20. A deposition apparatus comprising:
a chamber configured to accommodate a target substrate that is configured to discharge a target material, a deposition substrate on which a deposition layer including the target material is formed, and an electrode substrate in contact with the deposition substrate;
a voltage applying device configured to apply a negative DC voltage to the target substrate and a positive DC voltage to the electrode substrate;
a temperature measurement part configured to measure a temperature of the deposition substrate; and
a controller configured to calculate thermal stress of a first surface of the deposition layer in contact with the deposition substrate and thermal stress of a second surface opposite to the first surface by the temperature of the deposition substrate measured in the temperature measurement part, calculate a thermal stress difference that is a difference between the thermal stress of the first surface and the thermal stress of the second surface, compare an absolute value of the calculated thermal stress difference and a preset threshold thermal stress difference, control operation of the voltage applying device, and perform a deposition process for forming the deposition layer,
wherein the controller is configured to:
when the absolute value of the calculated thermal stress difference is greater than the preset threshold thermal stress difference, control that the voltage applying device in an operating state changes to a stop state, or control that the voltage applying device in the stop state maintains the stop state;
when the absolute value of the calculated thermal stress difference is equal to or less than the preset threshold thermal stress difference, control that the voltage applying device in the stop state changes to the operating state, or control that the voltage applying device in the operating state maintains the operating state; and
perform a plurality of deposition processes and form the deposition layer that has a final target thickness,
wherein, at a start time point when the absolute value of the calculated thermal stress is equal to the preset threshold thermal stress difference, the voltage applying device is in the stop state, and the controller is configured to control that the voltage applying device in the stop state changes to the operating state, or control that the voltage applying device in the stop state maintains the stop state and then changes to the operating state and control that the voltage applying device maintains the operating state until an s-th deposition layer having an s-th thickness is formed while the absolute value of the calculated thermal stress difference is equal to or less than the preset threshold thermal stress difference,
wherein, after the start time point, at a finish time point when the calculated thermal stress difference is a negative number and the absolute value of the calculated thermal stress difference is equal to the preset threshold thermal stress difference, the voltage applying device is in the stop state, and the controller is configured to control that the voltage applying device in the stop state maintains the stop state and then changes to the operating state and control that the voltage applying device maintains the operating state until an f-th deposition layer having an f-th thickness is formed and the deposition layer having the final target thickness is formed while the absolute value of the calculated thermal stress difference is equal to or less than the preset threshold thermal stress difference, and
wherein the s-th deposition layer and the f-th deposition layer are a portion of the deposition layer, the f-th thickness is greater than the s-th thickness, and the s-th thickness and the f-th thickness are less than the final target thickness.
